(19) United States
(12) Patent Application Publication
(10) Pub. No.: US 2025/0188314 A1
(43) Pub. Date: Jun. 12, 2025

(54) POLISHING COMPOSITION

(71) Applicant: FUJIMI INCORPORATED, Kiyosu-shi, Aichi (JP)

(72) Inventor: Shogo ONISHI, Tualatin, OR (US)

(73) Assignee: FUJIMI INCORPORATED, Kiyosu-shi, Aichi (JP)

(21) Appl. No.: 18/840,736

(22) PCT Filed: Feb. 16, 2023
(86) PCT No.: PCT/JP2023/005412

§ 371 Date: Aug. 22, 2024

Related U.S. Application Data
(60) Provisional application No. 63/317,668, filed on Mar. 8, 2022.

(51) Int. Cl. C09G 1/02

(52) U.S. Cl. CPC C09G 1/02

(57) ABSTRACT

[Problem] To provide polishing compositions and methods that can enable control over the SiN removal rate.

[Solution] Polishing compositions comprising an abrasive comprising cationic particles; a SiN polishing rate suppressor; and water, wherein the composition has a pH of less than 5, are capable of reducing the polishing rate of SiN to a second material X (e.g., spin-on carbon). Polishing compositions comprising an abrasive comprising cationic particles; a SiN polishing rate enhancer; and water, wherein the composition has a pH of less than or equal to 5, are capable of increasing the polishing rate of SiN to a second material X (e.g., spin-on carbon).

The application is based on U.S. Provisional Application No. 63/317,668 filed on Mar. 8, 2022, the disclosure content of which is herein incorporated by reference.

### TECHNICAL FIELD

The invention relates to a polishing composition.

### TECHNICAL FIELD

The following description of the background of the present technology is provided simply as an aid in understanding the present technology and is not admitted to describe or constitute prior art to the present technology.

The inventors have found that there exists an increased demand for polishing compositions and methods that are capable of controlling the removal rate of SiN relative to spin-on carbon (SoC) substrates.

Conventional polishing slurries do not afford adequate SiN polishing rate enhancement or suppression. Thus, polishing compositions and methods that enable control over the SiN removal rate can be of great commercial interest. It is against this backdrop that the polishing compositions and methods of the present disclosure were developed.

### SUMMARY OF INVENTION

In one aspect, which may be combined with any other aspect or embodiment, the present disclosure relates to a polishing composition comprising: an abrasive comprising cationic particles; a SiN polishing rate suppressor; and water, wherein the composition has a pH of less than or equal to 5.

In some embodiments, the SiN polishing rate suppressor comprises a basic amino acid. In some embodiments, the SiN polishing rate suppressor comprises at least one selected from the group consisting of: aspartic acid, glutamic acid, tyrosine, and cysteine. In some embodiments, the SiN suppressor is present at a concentration of 0.01% to 0.1% by weight, relative to the total weight of the composition.

In some embodiments, the cationic particles comprise zirconia particles or surface-modified silica particles comprising a terminal amine group. In some embodiments, the abrasive is present at a concentration of 0.1% to 5.0% by weight, relative to the total weight of the composition. In some embodiments, the cationic particles have an average primary particle size of 10 nm to 50 nm.

In some embodiments, the composition further comprises a pH adjuster comprising nitric acid. In some embodiments, the composition further comprises a surfactant. In some embodiments, the composition further comprises a wetting controller.

In another aspect, which may be combined with any other aspect or embodiment, the present disclosure relates to a method of polishing a substrate comprising SiN and a second material (X), comprising: polishing a surface of the substrate by contacting the surface with a composition according to any of the aforementioned aspects or embodiments. In some embodiments, the polishing removes the SiN and the second material (X) at a SiN:X removal rate ratio of 0.1 or less, wherein X represents the second material. In some embodiments, the removal rate ratio is 0.02 or less. In some embodiments, the removal rate ratio is 0.01 or less. In some embodiments, the second material comprises spin-on carbon (SoC).

In another aspect, which may be combined with any other aspect or embodiment, the present disclosure relates to a polishing composition comprising: an abrasive comprising cationic particles; a SiN polishing rate enhancer; and water, wherein the composition has a pH of less than or equal to 5.

In some embodiments, the SiN polishing rate enhancer comprises an acid having two or more carboxylic acid groups and one or more hydroxy groups. In some embodiments, the SiN polishing rate enhancer has a molecular weight of less than or equal to 600 g/mol. In some embodiments, the SiN enhancer is present at a concentration of 0.1% to 10% by weight, relative to the total weight of the composition.

In some embodiments, the cationic particles comprise zirconia particles or surface-modified silica particles comprising a terminal amine group. In some embodiments, the abrasive is present at a concentration of 0.1% to 5.0% by weight, relative to the total weight of the composition. In some embodiments, the cationic particles have an average primary particle size of 10 nm to 50 nm.

In some embodiments, the composition further comprises a pH adjuster comprising nitric acid. In some embodiments, the composition further comprises a surfactant. In some embodiments, the composition further comprises a wetting controller.

In another aspect, which may be combined with any other aspect or embodiment, the present disclosure relates to a method of polishing a substrate comprising SiN and a second material (X), comprising: polishing a surface of the substrate by contacting the surface with a composition according to any one of the aforementioned aspects or embodiments. In some embodiments, the polishing removes the SiN and the second material (X) at a SiN:X removal rate ratio of 0.1 or greater, wherein X represents the second material.

In some embodiments, the SiN:X removal rate ratio is 0.13 or greater. In some embodiments, the second material comprises spin-on carbon (SoC).

The present disclosure can encompass the following aspects and modes.

1. A polishing composition comprising: an abrasive comprising cationic particles; a SiN polishing rate suppressor; and water, wherein the composition has a pH of less than 5.

2. The polishing composition of 1., wherein the SiN polishing rate suppressor comprises an acidic amino acid, an amino acid comprising an aromatic hydrocarbon, or an amino acid comprising a sulfur atom.

3. The polishing composition of 1, or 2., wherein the SiN polishing rate suppressor comprises at least one selected from the group consisting of: aspartic acid, glutamic acid, tyrosine, and cysteine.

4. The polishing composition according to any of 1. to 3., wherein the cationic particles comprise zirconia particles or surface-modified silica particles comprising a terminal amine group.

5. The polishing composition according to any of 1. to 4., wherein the cationic particles are colloidal zirconia particles.

6. The polishing composition according to any of 1. to 5., wherein the SiN polishing rate suppressor is present at a concentration of greater than 0.0001 wt. % and 10 wt. % or less, relative to the total weight of the composition.

7. The polishing composition according to any of 1. to 6., wherein the composition further comprises a pH adjuster comprising nitric acid.

8. The polishing composition according to any of 1. to 7., wherein the composition comprises colloidal zirconia particles, at least one selected from the group consisting of: an acidic amino acid, an amino acid comprising an aromatic hydrocarbon, and an amino acid comprising a sulfur atom, and nitric acid.

9. The polishing composition according to any of 1. to 8., wherein the abrasive is present at a concentration of 0.1% to 5.0% by weight, relative to the total weight of the composition.

10. The polishing composition according to any of 1. to 9., wherein the cationic particles have an average primary particle size of 10 nm to 50 nm.

11. The polishing composition according to any of 1. to 10., wherein the composition further comprises a surfactant.

12. The polishing composition according to any of 1. to 11., wherein the composition further comprises a wetting controller.

13. The polishing composition of 12., wherein the wetting controller comprises N,N-dimethyldodecylamineoxide.

14. A method of polishing a substrate comprising SiN and a second material, comprising: polishing a surface of the substrate by contacting the surface with a composition according to any of 1. to 13., wherein the polishing rate of SiN is suppressed as compared with a case of polishing with a composition in which the SiN polishing rate suppressor in a composition according to any of 1. to 13. is not added.

15. The method of 14., wherein the second material comprises spin-on carbon (SoC).

16. The method of 14. or 15., wherein the polishing is made at a ratio (SiN:X removal rate ratio) of the polishing rate of SiN to the polishing rate of the second material X, of 0.067 or less.

17. The method according to any of 14. to 16., wherein the polishing is made at a ratio (SiN:X removal rate ratio) of the polishing rate of SiN to the polishing rate of the second material X, of less than 0.048.

18. A polishing composition comprising: an abrasive comprising cationic particles; a SiN polishing rate enhancer; and water, wherein the composition has a pH of less than or equal to 5.

19. The polishing composition of 18., wherein the SiN polishing rate enhancer comprises an acid comprising two or more carboxylic acid groups and one or more hydroxy groups.

20. The polishing composition of 18. or 19., wherein the SiN polishing rate enhancer has a molecular weight of less than 600 g/mol.

21. The polishing composition according to any of 18. to 20., wherein the cationic particles comprise zirconia particles or surface-modified silica particles comprising a terminal amine group.

22. The polishing composition according to any of 18. to 21., wherein the cationic particles are colloidal zirconia particles.

23. The polishing composition according to any of 18. to 22., wherein the SiN enhancer is present at a concentration of greater than 0.001 wt. % and 10 wt. % or less, relative to the total weight of the composition.

24. The polishing composition according to any of 18. to 23., wherein the composition further comprises a pH adjuster comprising nitric acid.

25. The polishing composition according to any of 18. to 24., wherein the composition comprises colloidal zirconia particles, an acid having two or more carboxylic acid groups and one or more hydroxy groups, and nitric acid.

26. The polishing composition according to any of 18. to 25., wherein the abrasive is present at a concentration of 0.1% to 5.0% by weight, relative to the total weight of the composition.

27. The polishing composition according to any of 18. to 26., wherein the cationic particles have an average primary particle size of 10 nm to 50 nm.

28. The polishing composition according to any of 18. to 27., wherein the composition further comprises a surfactant.

29. The polishing composition according to any of 18. to 28., wherein the composition further comprises a wetting controller.

30. The polishing composition of 29., wherein the wetting controller comprises N,N-dimethyldodecylamineoxide.

31. A method of polishing a substrate comprising SiN and a second material, comprising: polishing a surface of the substrate by contacting the surface with a composition according to any of 18. to 30., wherein the polishing rate of SiN is enhanced as compared with a case of polishing with a composition in which the SiN polishing rate enhancer in a composition according to any of 18. to 30. is not added.

32. The method of 31., wherein the second material comprises spin-on carbon (SoC).

33. The method of 31. or 32., wherein the polishing is made at a ratio (SiN:X removal rate ratio) of the polishing rate of SiN to the polishing rate of the second material X, of greater than 0.048.

34. The method according to any of 31. to 33., wherein the polishing is made at a ratio (SiN:X removal rate ratio) of the polishing rate of SiN to the polishing rate of the second material X, of 0.130 or greater.

Additional aspects and/or embodiments of the invention will be provided, without limitation, in the detailed description of the present technology set forth below. The following detailed description is exemplary and explanatory, but it is not intended to be limiting.

### DESCRIPTION OF EMBODIMENTS

Unless particularly described, operations, measurement of physical properties, and the like are made under conditions of room temperature (20 to 25° C.)/relative humidity 40 to 50% RH. Unless particularly noted, each ingredient constituting the polishing composition may be adopted in combination of two or more kinds thereof, and then included in the polishing composition, and the amount of use thereof, the amount of addition thereof, and the like each mean the total amount when two or more kinds are combined.

In one aspect, the present disclosure relates to polishing compositions which are capable of enhancing or suppressing the polishing rate of SiN relative to a second material (X) (e.g., spin-on carbon). In some embodiments, the present disclosure relates to a polishing composition comprising: an abrasive comprising cationic particles; a SiN polishing rate suppressor and/or a SiN polishing rate enhancer; and water.

### Abrasive

Polishing compositions according to the present disclosure comprise abrasive particles suitable for polishing a substrate comprising SiN and a second material. In some embodiments, the abrasive particles comprise one or more metal oxide particles, e.g., zirconia, hafnia, alumina, titania, silica, ceria, and any combination thereof. In some embodiments, the abrasive particles comprise colloidal silica, colloidal zirconia, or combinations thereof. If usual zirconia particles which are not colloidal zirconia particles are used, the entire surface of the substrate after polishing would be covered with scratches. Thus, in some embodiments, the cationic particles are colloidal zirconia particles. In addition, the abrasive particles may be a commercial product, synthetic product, or any combination thereof. In some embodiments, the abrasive particles may be cationic. Within the context of this application, “cationic” particles have a positive surface charge or zeta potential charge in the polishing composition. In Examples and Comparative Examples of the present application, in which the colloidal zirconia particles were used, the colloidal zirconia particles had a positive surface charge or zeta potential charge in the composition. The pH of the polishing composition can be 5 or less or less than 5. Zirconia, hafnia, alumina, titania, silica, and ceria can be “cationic” particles at pH of the polishing composition, of 5 or less or less than 5. In some embodiments, the abrasive particles do not comprise hafnia, alumina, titania, silica, ceria and any combination thereof. In some embodiments, 80 wt. % or greater, 85 wt. % or greater, 90 wt. % or greater, 95 wt. % or greater, 96 wt. % or greater, 97 wt. % or greater, 98 wt. % or greater, 99 wt. % or greater, or 100 wt. % of the abrasive particles (abrasive) are zirconia, colloidal zirconia, or any combination thereof.

In some embodiments, the abrasive particles are surface-modified by a chemical species covalently attached to the particle surface and having a terminal cationic group. In some embodiments, the abrasive particles comprise colloidal particles which are cationically modified, having an amino group or a quaternary ammonium salt group immobilized on the surface. In some embodiments, the colloidal particles are modified by aminoethyl trimethoxysilane, aminopropyl trimethoxysilane, aminoethyl triethoxysilane, aminopropyl triethoxysilane, aminopropyldimethyl ethoxysilane, aminopropylmethyl diethoxysilane, and aminobutyl triethoxysilane, or a silane coupling agent having a quaternary ammonium group such as N-trimethoxysilylpropyl-N,N,N-trimethylammonium on the surface of the abrasive particles. In some embodiments, the abrasive particles are not surface-modified by a chemical species. In some embodiments, the cationic particles comprise zirconia particles or surface-modified silica particles comprising a terminal amine group.

In some embodiments, the abrasive particles have an average primary particle size of greater than or equal to about 5 nm, greater than or equal to about 10 nm, greater than or equal to about 15 nm, greater than or equal to about 20 nm, greater than or equal to about 25 nm, greater than or equal to about 30 nm, greater than or equal to about 35 nm, greater than or equal to about 40 nm, greater than or equal to about 45 nm, greater than or equal to about 50 nm, greater than or equal to about 55 nm, greater than or equal to about 60 nm, greater than or equal to about 65 nm, greater than or equal to about 70 nm, greater than or equal to about 75 nm, greater than or equal to about 80 nm, greater than or equal to about 85 nm, greater than or equal to about 90 nm, greater than or equal to about 95 nm, greater than or equal to about 100 nm, greater than or equal to about 110 nm, greater than or equal to about 120 nm, greater than or equal to about 130 nm, greater than or equal to about 140 nm, greater than or equal to about 150 nm, greater than or equal to about 160 nm, greater than or equal to about 170 nm, greater than or equal to about 180 nm, greater than or equal to about 190 nm, greater than or equal to about 200 nm, greater than or equal to about 250 nm, greater than or equal to about 300 nm, greater than or equal to about 350 nm, greater than or equal to about 400 nm, greater than or equal to about 450 nm, greater than or equal to about 500 nm, or any range or value therein between. The “about XX” as used herein can be XX±10% in which “XX” is any number. In some embodiments, the abrasive particles have an average primary particle size of 5 nm or greater, 6 nm or greater, 7 nm or greater, 8 nm or greater, 9 nm or greater, 10 nm or greater, 11 nm or greater, 12 nm or greater, 13 nm or greater, 14 nm or greater, 15 nm or greater, 16 nm or greater, 17 nm or greater, 18 nm or greater, or 19 nm or greater, or any range or value therein between.

In some embodiments, the abrasive particles have an average primary particle size of less than or equal to about 500 nm, less than or equal to about 450 nm, less than or equal to about 400 nm, less than or equal to about 350 nm, less than or equal to about 300 nm, less than or equal to about 250 nm, less than or equal to about 200 nm, less than or equal to about 190 nm, less than or equal to about 180 nm, less than or equal to about 170 nm, less than or equal to about 160 nm, less than or equal to about 150 nm, less than or equal to about 140 nm, less than or equal to about 130 nm, less than or equal to about 120 nm, less than or equal to about 110 nm, less than or equal to about 100 nm, less than or equal to about 95 nm, less than or equal to about 90 nm, less than or equal to about 85 nm, less than or equal to about 80 nm, less than or equal to about 75 nm, less than or equal to about 70 nm, less than or equal to about 65 nm, less than or equal to about 60 nm, less than or equal to about 55 nm, less than or equal to about 50 nm, less than or equal to about 45 nm, less than or equal to about 40 nm, less than or equal to about 35 nm, less than or equal to about 30 nm, less than or equal to about 25 nm, less than or equal to about 20 nm, less than or equal to about 15 nm, less than or equal to about 10 nm, less than or equal to about 5 nm, or any range or value therein between. In some embodiments, the abrasive particles have an average primary particle size of 35 nm or less, 33 nm or less, 31 nm or less, 29 nm or less, 27 nm or less, 25 nm or less, or 23 nm or less, or any range or value therein between. If the average primary particle size of the abrasive particles is too large, many scratches may occur after polishing.

In some embodiments, the abrasive particles have an average primary particle size of about 5 nm to about 500 nm, about 5 nm to about 400 nm, about 5 nm to about 300 nm, about 5 nm to about 200 nm, about 5 nm to about 150 nm, about 5 nm to about 100 nm, about 5 nm to about 90 nm, about 5 nm to about 80 nm, about 5 nm to about 70 nm, about 5 nm to about 60 nm, about 5 nm to about 50 nm, about 5 nm to about 45 nm, about 5 nm to about 40 nm, about 10 nm to about 500 nm, about 10 nm to about 400 nm, about 10 nm to about 300 nm, about 10 nm to about 200 nm, about 10 nm to about 150 nm, about 10 nm to about 100 nm, about 10 nm to about 90 nm, about 10 nm to about 80 nm, about 10 nm to about 70 nm, about 10 nm to about 60 nm, about 10 nm to about 50 nm, about 10 nm to about 45 nm, about 10 nm to about 40 nm, about 20 nm to about 500 nm, about 20 nm to about 400 nm, about 20 nm to about 300 nm, about 20 nm to about 200 nm, about 20 nm to about 150 nm, about 20 nm to about 100 nm, about 20 nm to about 90 nm, about 20 nm to about 80 nm, about 20 nm to about 70 nm, about 20 nm to about 60 nm, about 20 nm to about 50 nm, about 20 nm to about 45 nm, about 20 nm to about 40 nm, about 30 nm to about 500 nm, about 30 nm to about 400 nm, about 30 nm to about 300 nm, about 30 nm to about 200 nm, about 30 nm to about 150 nm, about 30 nm to about 100 nm, about 30 nm to about 90 nm, about 30 nm to about 80 nm, about 30 nm to about 70 nm, about 30 nm to about 60 nm, about 30 nm to about 50 nm, about 30 nm to about 45 nm, about 30 nm to about 40 nm, about 40 nm to about 500 nm, about 40 nm to about 400 nm, about 40 nm to about 300 nm, about 40 nm to about 200 nm, about 40 nm to about 150 nm, about 40 nm to about 100 nm, about 40 nm to about 90 nm, about 40 nm to about 80 nm, about 40 nm to about 70 nm, about 40 nm to about 60 nm, about 40 nm to about 50 nm, about 50 nm to about 500 nm, about 50 nm to about 400 nm, about 50 nm to about 300 nm, about 50 nm to about 200 nm, about 50 nm to about 150 nm, about 50 nm to about 100 nm, about 50 nm to about 90 nm, about 50 nm to about 80 nm, about 50 nm to about 70 nm, about 50 nm to about 60 nm, or any range or value therein between. In some embodiments, the abrasive particles have an average primary particle size of 5 to 35 nm, 7 to 33 nm, 9 to 31 nm, 11 to 29 nm, 13 to 27 nm, 15 to 25 nm, or 17 to 23 nm, or any range or value therein between.

In some embodiments, the abrasive particles have an average secondary particle size of greater than or equal to about 5 nm, greater than or equal to about 10 nm, greater than or equal to about 15 nm, greater than or equal to about 20 nm, greater than or equal to about 25 nm, greater than or equal to about 30 nm, greater than or equal to about 35 nm, greater than or equal to about 40 nm, greater than or equal to about 45 nm, greater than or equal to about 50 nm, greater than or equal to about 55 nm, greater than or equal to about 60 nm, greater than or equal to about 65 nm, greater than or equal to about 70 nm, greater than or equal to about 75 nm, greater than or equal to about 80 nm, greater than or equal to about 85 nm, greater than or equal to about 90 nm, greater than or equal to about 95 nm, greater than or equal to about 100 nm, greater than or equal to about 110 nm, greater than or equal to about 120 nm, greater than or equal to about 130 nm, greater than or equal to about 140 nm, greater than or equal to about 150 nm, greater than or equal to about 160 nm, greater than or equal to about 170 nm, greater than or equal to about 180 nm, greater than or equal to about 190 nm, greater than or equal to about 200 nm, greater than or equal to about 250 nm, greater than or equal to about 300 nm, greater than or equal to about 350 nm, greater than or equal to about 400 nm, greater than or equal to about 450 nm, greater than or equal to about 500 nm, or any range or value therein between.

In some embodiments, the abrasive particles have an average secondary particle size of less than or equal to about 500 nm, less than or equal to about 450 nm, less than or equal to about 400 nm, less than or equal to about 350 nm, less than or equal to about 300 nm, less than or equal to about 250 nm, less than or equal to about 200 nm, less than or equal to about 190 nm, less than or equal to about 180 nm, less than or equal to about 170 nm, less than or equal to about 160 nm, less than or equal to about 150 nm, less than or equal to about 140 nm, less than or equal to about 130 nm, less than or equal to about 120 nm, less than or equal to about 110 nm, less than or equal to about 100 nm, less than or equal to about 95 nm, less than or equal to about 90 nm, less than or equal to about 85 nm, less than or equal to about 80 nm, less than or equal to about 75 nm, less than or equal to about 70 nm, less than or equal to about 65 nm, less than or equal to about 60 nm, less than or equal to about 55 nm, less than or equal to about 50 nm, less than or equal to about 45 nm, less than or equal to about 40 nm, less than or equal to about 35 nm, less than or equal to about 30 nm, less than or equal to about 25 nm, less than or equal to about 20 nm, less than or equal to about 15 nm, less than or equal to about 10 nm, less than or equal to about 5 nm, or any range or value therein between.

In some embodiments, the abrasive particles have an average secondary particle size of about 5 nm to about 500 nm, about 5 nm to about 400 nm, about 5 nm to about 300 nm, about 5 nm to about 200 nm, about 5 nm to about 150 nm, about 5 nm to about 100 nm, about 5 nm to about 90 nm, about 5 nm to about 80 nm, about 5 nm to about 70 nm, about 5 nm to about 60 nm, about 5 nm to about 50 nm, about 5 nm to about 45 nm, about 5 nm to about 40 nm, about 10 nm to about 500 nm, about 10 nm to about 400 nm, about 10 nm to about 300 nm, about 10 nm to about 200 nm, about 10 nm to about 150 nm, about 10 nm to about 100 nm, about 10 nm to about 90 nm, about 10 nm to about 80 nm, about 10 nm to about 70 nm, about 10 nm to about 60 nm, about 10 nm to about 50 nm, about 10 nm to about 45 nm, about 10 nm to about 40 nm, about 20 nm to about 500 nm, about 20 nm to about 400 nm, about 20 nm to about 300 nm, about 20 nm to about 200 nm, about 20 nm to about 150 nm, about 20 nm to about 100 nm, about 20 nm to about 90 nm, about 20 nm to about 80 nm, about 20 nm to about 70 nm, about 20 nm to about 60 nm, about 20 nm to about 50 nm, about 20 nm to about 45 nm, about 20 nm to about 40 nm, about 30 nm to about 500 nm, about 30 nm to about 400 nm, about 30 nm to about 300 nm, about 30 nm to about 200 nm, about 30 nm to about 150 nm, about 30 nm to about 100 nm, about 30 nm to about 90 nm, about 30 nm to about 80 nm, about 30 nm to about 70 nm, about 30 nm to about 60 nm, about 30 nm to about 50 nm, about 30 nm to about 45 nm, about 30 nm to about 40 nm, about 40 nm to about 500 nm, about 40 nm to about 400 nm, about 40 nm to about 300 nm, about 40 nm to about 200 nm, about 40 nm to about 150 nm, about 40 nm to about 100 nm, about 40 nm to about 90 nm, about 40 nm to about 80 nm, about 40 nm to about 70 nm, about 40 nm to about 60 nm, about 40 nm to about 50 nm, about 50 nm to about 500 nm, about 50 nm to about 400 nm, about 50 nm to about 300 nm, about 50 nm to about 200 nm, about 50 nm to about 150 nm, about 50 nm to about 100 nm, about 50 nm to about 90 nm, about 50 nm to about 80 nm, about 50 nm to about 70 nm, about 50 nm to about 60 nm, or any range or value therein between. In some embodiments, the abrasive particles have an average secondary particle size of 40 to 115 nm, 45 to 110 nm, 50 to 105 nm, 55 to 100 nm, 60 to 95 nm, 65 to 90 nm, or 70 to 85 nm, or any range or value therein between.

In some embodiments, the abrasive particles are present in the composition at a concentration by weight, relative to the total weight of the composition, of greater than or equal to about 0.1 wt. %, greater than or equal to about 0.15 wt. %, greater than or equal to about 0.2 wt. %, greater than or equal to about 0.25 wt. %, greater than or equal to about 0.3 wt. %, greater than or equal to about 0.35 wt. %, greater than or equal to about 0.4 wt. %, greater than or equal to about 0.45 wt. %, greater than or equal to about 0.5 wt. %, greater than or equal to about 0.55 wt. %, greater than or equal to about 0.60 wt. %, greater than or equal to about 0.65 wt. %, greater than or equal to about 0.7 wt. %, greater than or equal to about 0.75 wt. %, greater than or equal to about 0.8 wt. %, greater than or equal to about 0.85 wt. %, greater than or equal to about 0.9 wt. %, greater than or equal to about 0.95 wt. %, greater than or equal to about 1.0 wt. %, greater than or equal to about 1.1 wt. %, greater than or equal to about 1.2 wt. %, greater than or equal to about 1.3 wt. %, greater than or equal to about 1.4 wt. %, greater than or equal to about 1.5 wt. %, greater than or equal to about 1.6 wt. %, greater than or equal to about 1.7 wt. %, greater than or equal to about 1.8 wt. %, greater than or equal to about 1.9 wt. %, greater than or equal to about 2.0 wt. %, greater than or equal to about 2.5 wt. %, greater than or equal to about 3.0 wt. %, greater than or equal to about 3.5 wt. %, greater than or equal to about 4.0 wt. %, greater than or equal to about 4.5 wt. %, greater than or equal to about 5.0 wt. %, greater than or equal to about 5.5 wt. %, greater than or equal to about 6.0 wt. %, greater than or equal to about 6.5 wt. %, greater than or equal to about 7.0 wt. %, greater than or equal to about 7.5 wt. %, greater than or equal to about 8.0 wt. %, greater than or equal to about 8.5 wt. %, greater than or equal to about 9.0 wt. %, greater than or equal to about 9.5 wt. %, greater than or equal to about 10.0 wt. %, or any range or value therein between.

In some embodiments, the abrasive particles are present in the composition at a concentration by weight, relative to the total weight of the composition, of less than or equal to about 10.0 wt. %, less than or equal to about 9.5 wt. %, less than or equal to about 9.0 wt. %, less than or equal to about 8.5 wt. %, less than or equal to about 8.0 wt. %, less than or equal to about 7.5 wt. %, less than or equal to about 7.0 wt. %, less than or equal to about 6.5 wt. %, less than or equal to about 6.0 wt. %, less than or equal to about 5.5 wt. %, less than or equal to about 5.0 wt. %, less than or equal to about 4.5 wt. %, less than or equal to about 4.0 wt. %, less than or equal to about 3.5 wt. %, less than or equal to about 3.0 wt. %, less than or equal to about 2.5 wt. %, less than or equal to about 2.0 wt. %, less than or equal to about 1.9 wt. %, less than or equal to about 1.8 wt. %, less than or equal to about 1.7 wt. %, less than or equal to about 1.6 wt. %, less than or equal to about 1.5 wt. %, less than or equal to about 1.4 wt. %, less than or equal to about 1.3 wt. %, less than or equal to about 1.2 wt. %, less than or equal to about 1.1 wt. %, less than or equal to about 1.0 wt. %, less than or equal to about 0.95 wt. %, less than or equal to about 0.9 wt. %, less than or equal to about 0.85 wt. %, less than or equal to about 0.8 wt. %, less than or equal to about 0.75 wt. %, less than or equal to about 0.7 wt. %, less than or equal to about 0.65 wt. %, less than or equal to about 0.6 wt. %, less than or equal to about 0.55 wt. %, less than or equal to about 0.5 wt. %, less than or equal to about 0.45 wt. %, less than or equal to about 0.4 wt. %, less than or equal to about 0.35 wt. %, less than or equal to about 0.3 wt. %, less than or equal to about 0.25 wt. %, less than or equal to about 0.2 wt. %, less than or equal to about 0.15 wt. %, less than or equal to about 0.1 wt. %, or any range or value therein between.

In some embodiments, the abrasive particles are present in the composition at a concentration by weight, relative to the total weight of the composition, of about 0.1 wt. % to about 10.0 wt. %, about 0.2 wt. % to about 10.0 wt. %, about 0.3 wt. % to about 10.0 wt. %, about 0.4 wt. % to about 10.0 wt. %, about 0.5 wt. % to about 10.0 wt. %, about 0.6 wt. % to about 10.0 wt. %, about 0.7 wt. % to about 10.0 wt. %, about 0.8 wt. % to about 10.0 wt. %, about 0.9 wt. % to about 10.0 wt. %, about 1.0 wt. % to about 10.0 wt. %, about 2 wt. % to about 10.0 wt. %, about 3.0 wt. % to about 10.0 wt. %, about 4.0 wt. % to about 10.0 wt. %, about 5.0 wt. % to about 10.0 wt. %, about 0.1 wt. % to about 5 wt. %, about 0.2 wt. % to about 5 wt. %, about 0.3 wt. % to about 5 wt. %, about 0.4 wt. % to about 5 wt. %, about 0.5 wt. % to about 5 wt. %, about 0.6 wt. % to about 5 wt. %, about 0.7 wt. % to about 5 wt. %, about 0.8 wt. % to about 5 wt. %, about 0.9 wt. % to about 5 wt. %, about 1.0 wt. % to about 5 wt. %, about 0.1 wt. % to about 2.0 wt. %, about 0.2 wt. % to about 2.0 wt. %, about 0.3 wt. % to about 2.0 wt. %, about 0.4 wt. % to about 2.0 wt. %, about 0.5 wt. % to about 2.0 wt. %, about 0.6 wt. % to about 2.0 wt. %, about 0.7 wt. % to about 2.0 wt. %, about 0.8 wt. % to about 2.0 wt. %, about 0.9 wt. % to about 2.0 wt. %, about 1.0 wt. % to about 2.0 wt. %, about 0.1 wt. % to about 1.0 wt. %, about 0.2 wt. % to about 1.0 wt. %, about 0.3 wt. % to about 1.0 wt. %, about 0.4 wt. % to about 1.0 wt. %, about 0.5 wt. % to about 1.0 wt. %, about 0.6 wt. % to about 1.0 wt. %, about 0.1 wt. % to about 0.9 wt. %, about 0.1 wt. % to about 0.8 wt. %, about 0.1 wt. % to about 0.7 wt. %, about 0.2 wt. % to about 0.9 wt. %, about 0.2 wt. % to about 0.8 wt. %, about 0.2 wt. % to about 0.7 wt. %, about 0.3 wt. % to about 0.9 wt. %, about 0.3 wt. % to about 0.8 wt. %, about 0.3 wt. % to about 0.7 wt. %, about 0.4 wt. % to about 0.9 wt. %, about 0.4 wt. % to about 0.8 wt. %, about 0.4 wt. % to about 0.7 wt. %, about 0.5 wt. % to about 0.9 wt. %, about 0.5 wt. % to about 0.8 wt. %, about 0.5 wt. % to about 0.7 wt. %, about 0.6 wt. % to about 0.9 wt. %, about 0.6 wt. % to about 0.8 wt. %, about 0.6 wt. % to about 0.7 wt. % or any range or value therein between.

### SiN Polishing Rate Suppressor

In some embodiments, polishing compositions according to the present disclosure comprise a SiN polishing rate suppressor (“SiN suppressor”) suitable for reducing the polishing rate of SiN relative to a second material (e.g., spin-on carbon). In some embodiments, the SiN suppressor may comprise any suitable negatively-charged chemical species that reduces contact between the abrasive particles and a substrate comprising SiN by adsorbing to the particles, to the SiN surface, or both. In some embodiments, the SiN suppressor may be an anionic polymer, anionic surfactant, or an amino acid. In some embodiments, the SiN suppressor may comprise an acidic or basic amino acid. In some embodiments, the SiN polishing rate suppressor comprises at least one selected from the group consisting of: an acidic amino acid, an amino acid comprising an aromatic hydrocarbon, and an amino acid comprising a sulfur atom. In some embodiments, the aromatic hydrocarbon is benzene, naphthalene, or anthracene. In some embodiments, the SiN suppressor comprises arginine (e.g., 1-arginine), histidine, lysine, aspartic acid (e.g., 1-aspartic acid), glutamic acid (e.g., 1-glutamic acid), tyrosine, cysteine, serine, asparagine, glutamine, or any combination thereof. In some embodiments, the SiN suppressor comprises aspartic acid (e.g., 1-aspartic acid), glutamic acid (e.g., 1-glutamic acid), tyrosine, cysteine, or any combination thereof. In some embodiments, the SiN suppressor comprises aspartic acid (e.g., L-aspartic acid), glutamic acid (e.g., L-glutamic acid), cysteine, or any combination thereof. In some embodiments, the SiN suppressor comprises aspartic acid (e.g., L-aspartic acid), glutamic acid (e.g., L-glutamic acid), or any combination thereof.

In some embodiments, the SiN suppressor is present in the polishing composition at a concentration, by weight, relative to the total weight of the composition, of greater than or equal to about 0.001 wt. %, greater than or equal to about 0.005 wt. %, greater than or equal to about 0.01 wt. %, greater than or equal to about 0.05 wt. %, greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 0.6 wt. %, greater than or equal to about 0.7 wt. %, greater than or equal to about 0.8 wt. %, greater than or equal to about 0.9 wt. %, greater than or equal to about 1.0 wt. %, greater than or equal to about 1.5 wt. %, greater than or equal to about 2.0 wt. %, greater than or equal to about 2.5 wt. %, greater than or equal to about 3.0 wt. %, greater than or equal to about 3.5 wt. %, greater than or equal to about 4.0 wt. %, greater than or equal to about 4.5 wt. %, greater than or equal to about 5.0 wt. %, greater than or equal to about 5.5 wt. %, greater than or equal to about 6.0 wt. %, greater than or equal to about 6.5 wt. %, greater than or equal to about 7.0 wt. %, greater than or equal to about 7.5 wt. %, greater than or equal to about 8.0 wt. %, greater than or equal to about 8.5 wt. %, greater than or equal to about 9.0 wt. %, greater than or equal to about 9.5 wt. %, greater than or equal to about 10.0 wt. %, or any range or value therein between. In some embodiments, the SiN suppressor is present in the polishing composition at a concentration by weight, relative to the total weight of the composition, of greater than or equal to 0.00001 wt. %, greater than or equal to 0.00003 wt. %, greater than or equal to 0.00005 wt. %, greater than or equal to 0.00007 wt. %, greater than or equal to 0.00009 wt. %, greater than or equal to 0.0001 wt. %, greater than 0.0001 wt. %, greater than or equal to 0.0003 wt. %, greater than or equal to 0.0005 wt. %, greater than or equal to 0.0007 wt. %, greater than or equal to 0.0009 wt. %, greater than or equal to 0.001 wt. %, greater than 0.001 wt. %, greater than or equal to 0.003 wt. %, greater than or equal to 0.005 wt. %, greater than or equal to 0.009 wt. %, greater than or equal to 0.01 wt. %, greater than 0.01 wt. %, greater than or equal to 0.015 wt. %, greater than or equal to 0.02 wt. %, greater than 0.02 wt. %, greater than or equal to 0.025 wt. %, greater than or equal to 0.03 wt. %, greater than or equal to 0.035 wt. %, greater than or equal to 0.04 wt. %, greater than or equal to 0.045 wt. %, greater than or equal to 0.05 wt. %, greater than 0.05 wt. %, greater than or equal to 0.06 wt. %, greater than or equal to 0.07 wt. %, greater than or equal to 0.09 wt. %, greater than or equal to 0.1 wt. %, greater than 0.1 wt. %, greater than or equal to 0.15 wt. %, or greater than or equal to 0.2 wt. %, or any range or value therein between.

In some embodiments, the SiN polishing rate suppressor comprises at least one selected from the group consisting of: an acidic amino acid, an amino acid comprising an aromatic hydrocarbon, and an amino acid comprising a sulfur atom, and the concentration of the SiN polishing rate suppressor is greater than 0.0001 wt. %.

In some embodiments, the SiN suppressor is present in the polishing composition at a concentration, by weight, relative to the total weight of the composition, of less than or equal to about 10.0 wt. %, less than or equal to about 9.5 wt. %, less than or equal to about 9.0 wt. %, less than or equal to about 8.5 wt. %, less than or equal to about 8.0 wt. %, less than or equal to about 7.5 wt. %, less than or equal to about 7.0 wt. %, less than or equal to about 6.5 wt. %, less than or equal to about 6.0 wt. %, less than or equal to about 5.5 wt. %, less than or equal to about 5.0 wt. %, less than or equal to about 4.5 wt. %, less than or equal to about 4.0 wt. %, less than or equal to about 3.5 wt. %, less than or equal to about 3.0 wt. %, less than or equal to about 2.5 wt. %, less than or equal to about 2.0 wt. %, less than or equal to about 1.5 wt. %, less than or equal to about 1.0 wt. %, less than or equal to about 0.9 wt. %, less than or equal to about 0.8 wt. %, less than or equal to about 0.7 wt. %, less than or equal to about 0.6 wt. %, less than or equal to about 0.5 wt. %, less than or equal to about 0.4 wt. %, less than or equal to about 0.3 wt. %, less than or equal to about 0.2 wt. %, less than or equal to about 0.1 wt. %, less than or equal to about 0.05 wt. %, less than or equal to about 0.01 wt. %, less than or equal to about 0.005 wt. %, less than or equal to about 0.001 wt. %, or any range or value therein between.

In some embodiments, the SiN suppressor is present in the polishing composition at a concentration by weight, relative to the total weight of the composition, of about 0.001 wt. % to about 10.0 wt. %, about 0.005 wt. % to about 10.0 wt. %, about 0.01 wt. % to about 10.0 wt. %, about 0.05 wt. % to about 10.0 wt. %, about 0.1 wt. % to about 10.0 wt. %, about 0.5 wt. % to about 10.0 wt. %, about 1.0 wt. % to about 10.0 wt. %, about 5.0 wt. % to about 10.0 wt. %, about 0.001 wt. % to about 5.0 wt. %, about 0.001 wt. % to about 1.0 wt. %, about 0.001 wt. % to about 0.5 wt. %, about 0.001 wt. % to about 0.1 wt. %, about 0.005 wt. % to about 5.0 wt. %, about 0.01 wt. % to about 0.1 wt. %, about 0.01 wt. % to about 1.0 wt. %, about 0.05 wt. % to about 0.5 wt. %, or any range or value therein between. In some embodiments, the SiN suppressor is present in the polishing composition at a concentration by weight, relative to the total weight of the composition, of greater than 0.0001 wt. % and 10.0 wt. % or less, greater than 0.001 wt. % and 5.0 wt. % or less, greater than 0.01 wt. % and 3.0 wt. % or less, greater than or equal to 0.05 wt. % and 2.0 wt. % or less, or greater than 0.05 wt. % and 2.0 wt. % or less, or any range or value therein between.

### SiN Polishing Rate Enhancer

In some embodiments, polishing compositions according to the present disclosure comprise a SiN polishing rate enhancer (“SiN enhancer”) suitable for increasing the polishing rate of SiN relative to a second material (e.g., spin-on carbon). In some embodiments, the SiN enhancer may comprise any suitable chemical species promoting contact between the abrasive particles and a substrate comprising SiN or reducing contact between the abrasive particles and a second material (e.g., spin-on carbon). In some embodiments, the SiN enhancer may be an acid comprising one or more carboxylic acid groups (—COOH) and one or more hydroxy groups (—OH). In some embodiments, the SiN enhancer may be an acid comprising two or more carboxylic acid groups (—COOH) and one or more hydroxy groups (—OH). In some embodiments, the SiN enhancer may be an acid comprising, e.g., two or more carboxylic acid groups and at least 1, at least 2, at least 3, at least 4, or at least 5 hydroxy groups. In some embodiments, the SiN enhancer may be an acid comprising, e.g., two or more carboxylic acid groups and one or two hydroxy groups. In some embodiments, the number of carboxylic acid groups in the SiN enhancer is 6 or less, 5 or less, 4 or less, or 3 or less. In some embodiments, the number of hydroxy groups in the SiN enhancer is 6 or less, 5 or less, 4 or less, or, 3 or less. In some embodiments, the SiN enhancer comprises acetic acid, lactic acid, oxalic acid, malonic acid, tartaric acid, malic acid, valeric acid, citric acid, aconitic acid, succinic acid, glycolic acid, salicylic acid, glyceric acid, glutaric acid, adipic acid, pimelic acid, maleic acid, phthalic acid, hydroxycaprylic acid, hydroxycapric acid, a polyacrylic acid or combinations thereof. In some embodiments, the SiN enhancer comprises lactic acid, tartaric acid, malic acid, citric acid, a polyacrylic acid, or any combination thereof. In some embodiments, the SiN enhancer comprises tartaric acid, malic acid, citric acid, a polyacrylic acid, or any combination thereof. In some embodiments, the SiN enhancer comprises malic acid, citric acid, a polyacrylic acid, or any combination thereof.

In some embodiments, the SiN enhancer comprises a polyacrylic acid having a weight average molecular weight of greater than or equal to about 100 g/mol, greater than or equal to about 200 g/mol, greater than or equal to about 250 g/mol, greater than or equal to about 300 g/mol, greater than or equal to about 350 g/mol, greater than or equal to about 400 g/mol, greater than or equal to about 450 g/mol, greater than or equal to about 500 g/mol, greater than or equal to about 550 g/mol, greater than or equal to about 600 g/mol, greater than or equal to about 650 g/mol, greater than or equal to about 700 g/mol, greater than or equal to about 750 g/mol, greater than or equal to about 800 g/mol, greater than or equal to about 850 g/mol, greater than or equal to about 900 g/mol, greater than or equal to about 950 g/mol, greater than or equal to about 1,000 g/mol, greater than or equal to about 2,000 g/mol, greater than or equal to about 5,000 g/mol, greater than or equal to about 10,000 g/mol, greater than or equal to about 20,000 g/mol, greater than or equal to about 50,000 g/mol, greater than or equal to about 100,000 g/mol, greater than or equal to about 200,000 g/mol, greater than or equal to about 500,000 g/mol, greater than or equal to about 1,000,000 g/mol, or any range or value therein between.

In some embodiments, the SiN enhancer comprises a polyacrylic acid having a weight average molecular weight of less than or equal to 1,000,000 g/mol, less than or equal to about 500,000 g/mol, less than or equal to about 200,000 g/mol, less than or equal to about 100,000 g/mol, less than or equal to about 50,000 g/mol, less than or equal to about 20,000 g/mol, less than or equal to about 10,000 g/mol, less than or equal to about 5,000 g/mol, less than or equal to about 2,000 g/mol, less than or equal to about 1,000 g/mol, less than or equal to about 950 g/mol, less than or equal to about 900 g/mol, less than or equal to about 850 g/mol, less than or equal to about 800 g/mol, less than or equal to about 750 g/mol, less than or equal to about 700 g/mol, less than or equal to about 650 g/mol, less than or equal to about 600 g/mol, less than or equal to about 550 g/mol, less than or equal to about 500 g/mol, less than or equal to about 450 g/mol, less than or equal to about 400 g/mol, less than or equal to about 350 g/mol, less than or equal to about 300 g/mol, less than or equal to about 250 g/mol, less than or equal to about 200 g/mol, or any range or value therein between.

In some embodiments, the SiN enhancer is present in the polishing composition at a concentration, by weight, relative to the total weight of the composition, of greater than or equal to about 0.001 wt. %, greater than or equal to about 0.005 wt. %, greater than or equal to about 0.01 wt. %, greater than or equal to about 0.05 wt. %, greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 0.6 wt. %, greater than or equal to about 0.7 wt. %, greater than or equal to about 0.8 wt. %, greater than or equal to about 0.9 wt. %, greater than or equal to about 1.0 wt. %, greater than or equal to about 1.5 wt. %, greater than or equal to about 2.0 wt. %, greater than or equal to about 2.5 wt. %, greater than or equal to about 3.0 wt. %, greater than or equal to about 3.5 wt. %, greater than or equal to about 4.0 wt. %, greater than or equal to about 4.5 wt. %, greater than or equal to about 5.0 wt. %, greater than or equal to about 5.5 wt. %, greater than or equal to about 6.0 wt. %, greater than or equal to about 6.5 wt. %, greater than or equal to about 7.0 wt. %, greater than or equal to about 7.5 wt. %, greater than or equal to about 8.0 wt. %, greater than or equal to about 8.5 wt. %, greater than or equal to about 9.0 wt. %, greater than or equal to about 9.5 wt. %, greater than or equal to about 10.0 wt. %, or any range or value therein between. In some embodiments, the SiN enhancer is present in the polishing composition at a concentration by weight, relative to the total weight of the composition, of greater than or equal to 0.00001 wt. %, greater than or equal to 0.00003 wt. %, greater than or equal to 0.00005 wt. %, greater than or equal to 0.00007 wt. %, greater than or equal to 0.00009 wt. %, greater than or equal to 0.0001 wt. %, greater than 0.0001 wt. %, greater than or equal to 0.0003 wt. %, greater than or equal to 0.0005 wt. %, greater than or equal to 0.0007 wt. %, greater than or equal to 0.0009 wt. %, greater than or equal to 0.001 wt. %, greater than 0.001 wt. %, greater than or equal to 0.003 wt. %, greater than or equal to 0.005 wt. %, greater than or equal to 0.009 wt. %, greater than or equal to 0.01 wt. %, greater than 0.01 wt. %, greater than or equal to 0.015 wt. %, greater than or equal to 0.02 wt. %, greater than or equal to 0.025 wt. %, greater than or equal to 0.03 wt. %, greater than or equal to 0.035 wt. %, greater than or equal to 0.04 wt. %, greater than or equal to 0.045 wt. %, greater than or equal to 0.05 wt. %, greater than 0.05 wt. %, greater than or equal to 0.06 wt. %, greater than or equal to 0.07 wt. %, greater than or equal to 0.09 wt. %, greater than or equal to 0.1 wt. %, or greater than or equal to 0.2 wt. %, or any range or value therein between.

In some embodiments, the SiN enhancer comprises an acid comprising at least two carboxylic acid groups and the concentration of the SiN enhancer is greater than 0.0001 wt. % or greater than 0.001 wt. %.

In some embodiments, the SiN enhancer is present in the polishing composition at a concentration, by weight, relative to the total weight of the composition, of less than or equal to about 10.0 wt. %, less than or equal to about 9.5 wt. %, less than or equal to about 9.0 wt. %, less than or equal to about 8.5 wt. %, less than or equal to about 8.0 wt. %, less than or equal to about 7.5 wt. %, less than or equal to about 7.0 wt. %, less than or equal to about 6.5 wt. %, less than or equal to about 6.0 wt. %, less than or equal to about 5.5 wt. %, less than or equal to about 5.0 wt. %, less than or equal to about 4.5 wt. %, less than or equal to about 4.0 wt. %, less than or equal to about 3.5 wt. %, less than or equal to about 3.0 wt. %, less than or equal to about 2.5 wt. %, less than or equal to about 2.0 wt. %, less than or equal to about 1.5 wt. %, less than or equal to about 1.0 wt. %, less than or equal to about 0.9 wt. %, less than or equal to about 0.8 wt. %, less than or equal to about 0.7 wt. %, less than or equal to about 0.6 wt. %, less than or equal to about 0.5 wt. %, less than or equal to about 0.4 wt. %, less than or equal to about 0.3 wt. %, less than or equal to about 0.2 wt. %, less than or equal to about 0.1 wt. %, less than or equal to about 0.05 wt. %, less than or equal to about 0.01 wt. %, less than or equal to about 0.005 wt. %, less than or equal to about 0.001 wt. %, or any range or value therein between.

In some embodiments, the SiN enhancer is present in the polishing composition at a concentration, by weight, relative to the total weight of the composition, of about 0.001 wt. % to about 10.0 wt. %, about 0.005 wt. % to about 10.0 wt. %, about 0.01 wt. % to about 10.0 wt. %, about 0.05 wt. % to about 10.0 wt. %, about 0.1 wt. % to about 10.0 wt. %, about 0.5 wt. % to about 10.0 wt. %, about 1.0 wt. % to about 10.0 wt. %, about 5.0 wt. % to about 10.0 wt. %, about 0.001 wt. % to about 5.0 wt. %, about 0.001 wt. % to about 1.0 wt. %, about 0.001 wt. % to about 0.5 wt. %, about 0.001 wt. % to about 0.1 wt. %, about 0.005 wt. % to about 5.0 wt. %, about 0.01 wt. % to about 0.1 wt. %, about 0.01 to about 1.0 wt. %, about 0.05 wt. % to about 0.5 wt. %, or any range or value therein. In some embodiments, the SiN enhancer is present in the polishing composition at a concentration by weight, relative to the total weight of the composition, of greater than 0.0001 wt. % and 10.0 wt. % or less, greater than 0.001 wt. % and 5.0 wt. % or less, greater than 0.005 wt. % and 4.0 wt. % or less, greater than 0.01 wt. % and 3.0 wt. % or less, greater than or equal to 0.05 wt. % and 2.0 wt. % or less, or greater than 0.05 wt. % and 2.0 wt. % or less, or any range or value therein between.

### Aqueous Carrier

A polishing composition according to the present disclosure comprises water as an aqueous carrier. Examples of the aqueous carrier can include water; alcohols such as methanol, ethanol, and ethylene glycol; ketones such as acetone, and any mixture thereof. Among them, the aqueous carrier is preferably water. In other words, according to a preferred mode of the invention, the aqueous carrier comprises water. According to a more preferred mode of the invention, the aqueous carrier substantially consists of water. The “substantially” means that the aqueous carrier can comprise any other aqueous carrier than water as long as the objects and effects of the invention can be achieved, and more specifically, the aqueous carrier preferably substantially consists of 90 mass % or greater and 100 mass % or less of water and 0 mass % or greater and 10 mass % or less of any other aqueous carrier than water, and more preferably substantially consists of 99 mass % or greater and 100 mass % or less of water and 0 mass % or greater and 1 mass % or less of any other aqueous carrier than water. Most preferably, the aqueous carrier is water.

The aqueous carrier is preferably water comprising no impurities as far as possible, and preferably, e.g., water in which the total content of transition metal ions is 100 ppb or less, in order not to inhibit any action of ingredients in the composition. Specifically, deionized water (ion exchange water), pure water, ultrapure water, or distilled water, from which impurity ions are removed by an ion exchange resin and foreign materials are removed through a filter, is preferably used.

### Surfactant

In some embodiments, a polishing composition according to the present disclosure comprises a surfactant. In some embodiments, the surfactant may be a cationic surfactant, amphoteric surfactant, nonionic surfactant, or anionic surfactant. In some embodiments, the surfactant is a cationic surfactant. Non-limiting examples of the cationic surfactant include alkyl trimethyl ammonium salts, alkyl dimethyl ammonium salts, alkyl benzyl dimethyl ammonium salts, alkylamine salts, and any combination thereof. In some embodiments, a polishing composition according to the present disclosure dose not comprise an alkyl trimethyl ammonium salt, an alkyl dimethyl ammonium salt, an alkyl benzyl dimethyl ammonium salt, an alkylamine salt, and any combination thereof.

In some embodiments, the surfactant is present in the polishing composition at a concentration, by weight, relative to the total weight of the composition, of greater than or equal to about 0.001 wt. %, greater than or equal to about 0.005 wt. %, greater than or equal to about 0.01 wt. %, greater than or equal to about 0.05 wt. %, greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 0.6 wt. %, greater than or equal to about 0.7 wt. %, greater than or equal to about 0.8 wt. %, greater than or equal to about 0.9 wt. %, greater than or equal to about 1.0 wt. %, greater than or equal to about 1.5 wt. %, greater than or equal to about 2.0 wt. %, greater than or equal to about 2.5 wt. %, greater than or equal to about 3.0 wt. %, greater than or equal to about 3.5 wt. %, greater than or equal to about 4.0 wt. %, greater than or equal to about 4.5 wt. %, greater than or equal to about 5.0 wt. %, greater than or equal to about 5.5 wt. %, greater than or equal to about 6.0 wt. %, greater than or equal to about 6.5 wt. %, greater than or equal to about 7.0 wt. %, greater than or equal to about 7.5 wt. %, greater than or equal to about 8.0 wt. %, greater than or equal to about 8.5 wt. %, greater than or equal to about 9.0 wt. %, greater than or equal to about 9.5 wt. %, greater than or equal to about 10.0 wt. %, or any range or value therein between.

In some embodiments, the surfactant is present in the polishing composition at a concentration, by weight, relative to the total weight of the composition, of less than or equal to about 10.0 wt. %, less than or equal to about 9.5 wt. %, less than or equal to about 9.0 wt. %, less than or equal to about 8.5 wt. %, less than or equal to about 8.0 wt. %, less than or equal to about 7.5 wt. %, less than or equal to about 7.0 wt. %, less than or equal to about 6.5 wt. %, less than or equal to about 6.0 wt. %, less than or equal to about 5.5 wt. %, less than or equal to about 5.0 wt. %, less than or equal to about 4.5 wt. %, less than or equal to about 4.0 wt. %, less than or equal to about 3.5 wt. %, less than or equal to about 3.0 wt. %, less than or equal to about 2.5 wt. %, less than or equal to about 2.0 wt. %, less than or equal to about 1.5 wt. %, less than or equal to about 1.0 wt. %, less than or equal to about 0.9 wt. %, less than or equal to about 0.8 wt. %, less than or equal to about 0.7 wt. %, less than or equal to about 0.6 wt. %, less than or equal to about 0.5 wt. %, less than or equal to about 0.4 wt. %, less than or equal to about 0.3 wt. %, less than or equal to about 0.2 wt. %, less than or equal to about 0.1 wt. %, less than or equal to about 0.05 wt. %, less than or equal to about 0.01 wt. %, less than or equal to about 0.005 wt. %, less than or equal to about 0.001 wt. %, or any range or value therein between.

In some embodiments, the surfactant is present in the polishing composition at a concentration, by weight, relative to the total weight of the composition, of about 0.001 wt. % to about 10.0 wt. %, about 0.005 wt. % to about 10.0 wt. %, about 0.01 wt. % to about 10.0 wt. %, about 0.05 wt. % to about 10.0 wt. %, about 0.1 wt. % to about 10.0 wt. %, about 0.5 wt. % to about 10.0 wt. %, about 1.0 wt. % to about 10.0 wt. %, about 5.0 wt. % to about 10.0 wt. %, about 0.001 wt. % to about 5.0 wt. %, about 0.001 wt. % to about 1.0 wt. %, about 0.001 wt. % to about 0.5 wt. %, about 0.001 wt. % to about 0.1 wt. %, about 0.005 wt. % to about 5.0 wt. %, about 0.01 wt. % to about 0.1 wt. %, about 0.01 to about 1.0 wt. %, about 0.05 wt. % to about 0.5 wt. %, or any range or value therein.

### pH Adjusting Agent

In some embodiments, a composition according to the present disclosure may further comprise one or more pH adjusting agents to adjust the pH to a selected pH value. In some embodiments, the “SiN polishing rate enhancer”, the “SiN polishing rate suppressor”, and the “surfactant” are not considered to be pH adjusters. A pH adjuster described below, if included in any of the “SiN polishing rate enhancer”, the “SiN polishing rate suppressor”, and the “surfactant”, may belong thereto.

The pH adjusting agent is not particularly limited, and any suitable pH adjusting agent may be used to bring the pH of the composition into any desired range, as discussed above. In some embodiments, the one or more pH adjusting agents may comprise, consist essentially of, or consist of an inorganic compound, an organic compound, or combinations thereof. In some embodiments, the one or more pH adjusting agents may comprise inorganic acids (e.g., hydrochloric acid, hydrobromic acid, hydroiodic acid, sulfuric acid, nitric acid, boric acid, carbonic acid, hypophosphorous acid, phosphorous acid, and phosphoric acid); organic acids (e.g., carboxylic acids such as citric acid, formic acid, acetic acid, propionic acid, benzoic acid, salicylic acid, glyceric acid, oxalic acid, malonic acid, succinic acid, maleic acid, phthalic acid, malic acid, tartaric acid, and lactic acid); and/or organic sulfuric acids (e.g., methane sulfonic acid, ethane sulfonic acid, isethionic acid, etc.). In some embodiments, the one or more pH adjusting agents may comprise a divalent or higher acid of the above acid(s) (e.g., sulfuric acid, carbonic acid, phosphoric acid, oxalic acid, etc.), which may be in the form of a base when one or more protons (H⁺) can be released (e.g., ammonium hydrogen carbonate or ammonium hydrogen phosphate), but any counter-ion may be used (e.g., weakly basic cations, such as ammonium, triethanolamine, etc.). In some embodiments, the one or more pH adjusting agents comprises nitric acid. In some embodiments, the pH adjuster is nitric acid. In some embodiments, the composition comprises colloidal zirconia particles, at least one selected from the group consisting of: an acidic amino acid, an amino acid comprising an aromatic hydrocarbon, and an amino acid comprising a sulfur atom, and nitric acid. Here, the concentration of the SiN polishing rate enhancer which is at least one selected from the group consisting of: an acidic amino acid, an amino acid comprising an aromatic hydrocarbon, and an amino acid comprising a sulfur atom is greater than 0.0001 wt. % or greater than 0.001 wt. %, relative to the total weight of the composition. This nitric acid may be added at a concentration so that the composition has a desired pH. In some embodiments, the SiN polishing rate enhancer comprises colloidal zirconia particles, an acid having two or more carboxylic acid groups and one or more hydroxy groups, and nitric acid. Here, the concentration of the SiN polishing rate enhancer which is an acid having two or more carboxylic acid groups and one or more hydroxy groups is greater than 0.0001 wt. % or greater than 0.001 wt. %, relative to the total weight of the composition. This nitric acid may be added at a concentration so that the composition has a desired pH.

In some embodiments, the one or more pH adjusting agents may comprise one or more hydroxides of alkali metals (e.g., NaOH, KOH), or salts thereof (e.g., carbonates, hydrogen carbonates, sulfates, acetates, etc.); quaternary ammonium compounds (e.g., tetramethylammonium, tetraethylammonium, tetrabutylammonium, etc.); quaternary ammonium hydroxides (e.g., tetramethylammonium hydroxide, tetraethylammonium hydroxide, tetrabutylammonium hydroxide) or a salts thereof; ammonia; amines; or any other suitable pH adjusting agent. In some embodiments, the composition does not comprise such any other suitable pH adjuster.

The pH adjust agent may be present in any amount suitable to achieve a desired pH value, as discussed above.

### pH of Composition

In some embodiments, the pH of the composition can be measured at a temperature of the composition of 25° C. with Thermo Scientific VSTAR94 as measurement equipment.

In some embodiments, the pH of the composition is acidic (e.g., less than 7). In some embodiments, the pH of the composition is less than 7, less than or equal to 6.9, less than or equal to 6.8, less than or equal to 6.7, less than or equal to 6.6, less than or equal to 6.5, less than or equal to 6.4, less than or equal to 6.3, less than or equal to 6.2, less than or equal to 6.1, less than or equal to 6.0, less than or equal to 5.9, less than or equal to 5.8, less than or equal to 5.7, less than or equal to 5.6, less than or equal to 5.5, less than or equal to 5.4, less than or equal to 5.3, less than or equal to 5.2, less than or equal to 5.1, less than or equal to 5.0, less than or equal to 4.9, less than or equal to 4.8, less than or equal to 4.7, less than or equal to 4.6, less than or equal to 4.5, less than or equal to 4.4, less than or equal to 4.3, less than or equal to 4.2, less than or equal to 4.1, less than or equal to 4.0, less than or equal to 3.9, less than or equal to 3.8, less than or equal to 3.7, less than or equal to 3.6, less than or equal to 3.5, less than or equal to 3.4, less than or equal to 3.3, less than or equal to 3.2, less than or equal to 3.1, less than or equal to 3.0, less than or equal to 2.9, less than or equal to 2.8, less than or equal to 2.7, less than or equal to 2.6, less than or equal to 2.5, less than or equal to 2.4, less than or equal to 2.3, less than or equal to 2.2, less than or equal to 2.1, less than or equal to 2.0, or any range or value therein between. In some embodiments, the pH of the composition is less than 5.0, less than 4.0, less than 3.0, less than 2.4, less than 2.0, less than or equal to 1.9, less than or equal to 1.8, less than or equal to 1.7, less than or equal to 1.6, less than or equal to 1.5, less than or equal to 1.4, less than or equal to 1.3, or less than or equal to 1.2, or any range or value therein between. In some embodiments, if the polishing composition comprises the SiN polishing rate suppressor, the pH of the composition is less than 5.0, less than or equal to 4.0, less than 4.0, less than or equal to 3.0, less than 3.0, less than or equal to 2.4, less than 2.4, less than 2.0, less than or equal to 1.9, less than or equal to 1.8, less than or equal to 1.7, less than or equal to 1.6, less than or equal to 1.5, less than or equal to 1.4, less than or equal to 1.3, or less than or equal to 1.2, or any range or value therein between. In some embodiments, if the polishing composition comprises the SiN polishing rate enhancer, the pH of the composition is less than or equal to 5.0, less than 5.0, less than 4.0, less than or equal to 3.0, less than 3.0, less than or equal to 2.9, less than or equal to 2.8, less than or equal to 2.7, less than or equal to 2.6, or less than or equal to 2.5, or any range or value therein between.

In some embodiments, the pH of the composition is greater than or equal to 1.0, greater than or equal to 1.1, greater than or equal to 1.2, greater than or equal to 1.3, greater than or equal to 1.4, greater than or equal to 1.5, greater than or equal to 1.6, greater than or equal to 1.7, greater than or equal to 1.8, greater than or equal to 1.9, greater than or equal to 2.0, greater than or equal to 2.1, greater than or equal to 2.2, greater than or equal to 2.3, greater than or equal to 2.4, greater than or equal to 2.5, greater than or equal to 2.6, greater than or equal to 2.7, greater than or equal to 2.8, greater than or equal to 2.9, greater than or equal to 3.0, greater than or equal to 3.1, greater than or equal to 3.2, greater than or equal to 3.3, greater than or equal to 3.4, greater than or equal to 3.5, greater than or equal to 3.6, greater than or equal to 3.7, greater than or equal to 3.8, greater than or equal to 3.9, greater than or equal to 4.0, greater than or equal to 4.1, greater than or equal to 4.2, greater than or equal to 4.3, greater than or equal to 4.4, greater than or equal to 4.5, greater than or equal to 4.6, greater than or equal to 4.7, greater than or equal to 4.8, greater than or equal to 4.9, greater than or equal to 5.0, greater than or equal to 5.1, greater than or equal to 5.2, greater than or equal to 5.3, greater than or equal to 5.4, greater than or equal to 5.5, greater than or equal to 5.6, greater than or equal to 5.7, greater than or equal to 5.8, greater than or equal to 5.9, greater than or equal to 6.0, or any range or value therein between.

In some embodiments, the pH of the composition is from 2 to 6, from 2 to 5, from 2 to 4, from 2 to 3, from 3 to 6, from 3 to 5, from 3 to 4, from 4 to 6, from 4 to 5, or from 5 to 6. In some embodiments, the pH of the composition is about 1, about 1.5, about 2, about 2.5, about 3, about 3.5, about 4, about 4.5, about 5, about 5.5, about 6, or about 6.5. In some embodiments, if the polishing composition comprises the SiN polishing rate suppressor, the pH of the composition is 1.0 to 4.9, 1.0 to 4.0, 1.0 to 3.9, 1.0 to 3.0, 1.0 to 2.9, 1.0 to 2.4, 1.1 to 2.4, 1.1 to 2.0, 1.1 to 1.9, or 1.1 to 1.8 or any range or value therein between. In some embodiments, if the polishing composition comprises the SiN polishing rate enhancer, the pH of the composition is 1.1 to 5, 1.2 to 4, 1.3 to 3.5, 1.4 to 3.2, 1.4 to 3.0, 1.4 to 2.9, 1.4 to 2.4, 1.5 to 2.8, 1.6 to 2.7, or 1.7 to 2.6 or any range or value therein between.

### Other Additives

In some embodiments, the composition may comprise other additives at any concentration. However, it is desirable not to add unnecessary components, which may cause the presence of surface defects. Thus, it is preferred that any other additives are present in relatively small concentrations (e.g., 0.1 wt. % or less, 0.05 wt. % or less, 0.01 wt. % or less, 0.005 wt. % or less, 0.001 wt. % or less, 0.0005 wt. % or less, 0.0001 wt. % or less, 0.0001 wt. % to 0.1 wt. %, 0.0001 wt. % to 0.01 wt. %, or 0.0001 wt. % to 0.001 wt. %, etc.) if they are present at all. Examples of other additives include antiseptic agents, biocides (e.g., isothiazolinones such as methylisothiazolinone (“MIT”), benzisothiazolinone (“BIT”), etc.), dissolved gases, oxidizing agents, wetting controllers (“wetting agents,” e.g., hydroxyethylcellulose, N,N-dimethyldodecylamineoxide, polyvinyl alcohol (PVA), polyvinylpyrrolidone (PVP), poly(N-vinylacetamide) (PNVA), polypropylene glycol (PPG), polyethylene glycol (PEG), PEG-PPG copolymers or block copolymers (e.g., PEG-PPG, PEG-PPG-PEG, PPG-PEG-PPG, etc.), and combinations thereof), and the like. In some embodiments, the composition comprises methylisothiazolinone (MIT) or N,N-dimethyldodecylamineoxide as any other additives. In some embodiments, the composition comprises N,N-dimethyldodecylamineoxide as any other additives. In some embodiments, the composition does not comprise hydroxyethylcellulose, N,N-dimethyldodecylamineoxide, polyvinyl alcohol (PVA), polyvinylpyrrolidone (PVP), poly(N-vinylacetamide) (PNVA), polypropylene glycol (PPG), polyethylene glycol (PEG), a PEG-PPG copolymer or a block copolymer (e.g., PEG-PPG, PEG-PPG-PEG, PPG-PEG-PPG, etc.), and any combination thereof) as any other additives.

In some embodiments, the composition is consisting essentially of an abrasive comprising cationic particles, a SiN polishing rate suppressor or a SiN polishing rate enhancer and water, and at least one selected from the group consisting of a pH adjuster, a surfactant, an antiseptic agent, a biocide, a dissolved gas, an oxidizing agent and a wetting controller. Herein, the phrase “composition being consisting essentially of Z₁, Z₂, Z₃, . . . Zₚ (p is an integer of 2 or greater)” means that the total content of Z₁, Z₂, Z₃, . . . Zₚ is greater than 99 mass % (upper limit: 100 mass %) relative to the composition.

In some embodiments, the composition is consisting essentially of an abrasive comprising cationic particles, a SiN polishing rate suppressor or a SiN polishing rate enhancer and water, and at least one selected from the group consisting of a pH adjuster, a biocide and a wetting controller. In some embodiments, the composition is consisting of an abrasive comprising cationic particles, a SiN polishing rate suppressor and water, and at least one selected from the group consisting of a pH adjuster, a biocide and a wetting controller.

In some embodiments, the composition is consisting essentially of an abrasive comprising cationic particles, a SiN polishing rate suppressor or a SiN polishing rate enhancer and water, and at least one selected from the group consisting of nitric acid, methylisothiazolinone (MIT) and N,N-dimethyldodecylamineoxide. In some embodiments, the composition is consisting of an abrasive comprising cationic particles, a SiN polishing rate suppressor and water, and at least one selected from the group consisting of nitric acid, methylisothiazolinone (MIT) and N,N-dimethyldodecylamineoxide.

### Polishing Methods

In another aspect, the present disclosure relates to a method of polishing a substrate comprising SiN and a second material (X), comprising: polishing a surface of the substrate by contacting the surface with a composition according to any one of the aforementioned aspects or embodiments. In some embodiments, the second material (X) is a carbonaceous material (e.g., spin-on carbon), an oxide (e.g., silica), a metal (e.g., Al), TEOS, bare silicon, polycrystalline silicon (“poly-Si”), amorphous silicon, or any combination thereof.

In some embodiments the polishing composition comprises: abrasive particles, a SiN polishing rate suppressor, and water. In some embodiments, the polishing composition suppresses the ratio (SiN:X removal rate ratio) of the polishing rate of SiN to the polishing rate of a second material (X) (e.g., spin-on carbon) and removes the SiN and the second material X at a SiN:X removal rate ratio of 0.1 or less.

The polishing rate of SiN (A/min) to the polishing rate of a second material (X) (e.g., spin-on carbon) (Å/min) (SiN:X removal rate ratio) is preferably lower. In some embodiments, the SiN:X removal rate ratio is equal to or less than about 0.1 (1:10), equal to or less than about 0.083 (1:12), equal to or less than about 0.067 (1:15), equal to or less than about 0.05 (1:20), equal to or less than about 0.04 (1:25), equal to or less than about 0.033 (1:30), equal to or less than about 0.025 (1:40), equal to or less than about 0.02 (1:50), equal to or less than about 0.013 (1:75), equal to or less than about 0.01 (1:100), equal to or less than about 0.005 (1:200), equal to or less than about 0.0033 (1:300), equal to or less than about 0.0025 (1:400), equal to or less than about 0.002 (1:500), or any range or value therein between. In some embodiments, the polishing rate of SiN (Å/min) to the polishing rate of a second material (X) (e.g., spin-on carbon) (Å/min) (SiN:X removal rate ratio) is less than 0.048, 0.040 or less, less than 0.040, less than 0.039, 0.035 or less, 0.030 or less, 0.025 or less, 0.020 or less, 0.015 or less, 0.011 or less, 0.010 or less, 0.009 or less, 0.008 or less, 0.007 or less, 0.006 or less, 0.005 or less, 0.004 or less, 0.003 or less, or any range or value therein between. In some embodiments, the polishing rate of SiN (Å/min) to the polishing rate of a second material (X) (e.g., spin-on carbon) (Å/min) (SiN:X removal rate ratio) is, e.g., 0.001 or greater or 0.002 or greater, or any range or value therein between.

In some embodiments the polishing composition comprises: abrasive particles, a SiN polishing rate enhancer, and water. In some embodiments, the polishing composition enhances the polishing rate of SiN relative to a second material (X) (e.g., spin-on carbon) and removes the SiN and the second material X at a SiN:X removal rate ratio of 0.1 or greater.

The polishing rate of SiN (Å/min) to the polishing rate of a second material (X) (e.g., spin-on carbon) (Å/min) (SiN:X removal rate ratio) is preferably higher. In some embodiments, the SiN:X removal rate ratio is equal to or greater than about 0.1 (1:10), equal to or greater than about 0.125 (1:8), equal to or greater than about 0.13 (1:7.5), equal to or greater than about 0.2 (1:5), equal to or greater than about 0.25 (1:4), equal to or greater than about 0.330 (1:3), equal to or greater than about 0.340, equal to or greater than about 0.4 (1:2.5), equal to or greater than about 1 (1:1), equal to or greater than about 2 (2:1), equal to or greater than about 3 (3:1), equal to or greater than about 4 (4:1), equal to or greater than about 5 (5:1), equal to or greater than about 10 (10:1), equal to or greater than about 20 (20:1), equal to or greater than about 50 (50:1), or equal to or greater than about 100 (100:1), or any range or value therein between. In some embodiments, the polishing rate of SiN (Å/min) to the polishing rate of a second material (X) (e.g., spin-on carbon) (Å/min) (SiN:X removal rate ratio) is greater than 0.048, 0.050 or greater, 0.060 or greater, 0.070 or greater, 0.080 or greater, 0.090 or greater, 0.10 or greater, greater than 0.12, 0.15 or greater, greater than 0.15, 0.20 or greater, 0.25 or greater, 0.30 or greater, 0.33 or greater, 0.34 or greater, or 0.344 or greater, or any range or value therein between. In some embodiments, the polishing rate of SiN (Å/min) to the polishing rate of a second material (X) (e.g., spin-on carbon) (Å/min) (SiN:X removal rate ratio) is, e.g., 1.0 or less, 0.8 or less, or 0.6 or less, or any range or value therein between.

In some embodiments, the SiN removal rate is about 1 Å/min, about 2 Å/min, about 3 Å/min, about 4 Å/min, about 5 Å/min, about 6 Å/min, about 7 Å/min, about 8 Å/min, about 9 Å/min, about 10 Å/min, about 15 Å/min, about 20 Å/min, about 25 Å/min, about 30 Å/min, about 35 Å/min, about 40 Å/min, about 45 Å/min, about 50 Å/min, about 55 Å/min, about 60 Å/min, about 70 Å/min, about 75 Å/min, about 80 Å/min, about 85 Å/min, about 90 Å/min, about 100 Å/min, about 125 Å/min, about 150 Å/min, about 175 Å/min, about 200 Å/min, about 225 Å/min, about 250 Å/min, about 275 Å/min, about 300 Å/min, about 350 Å/min, about 400 Å/min, about 450 Å/min, about 500 Å/min, about 550 Å/min, about 600 Å/min, about 650 Å/min, about 700 Å/min, about 750 Å/min, about 800 Å/min, about 850 Å/min, about 900 Å/min, about 950 Å/min, or about 1,000 Å/min or more. The term “greater than or equal to” is related to a numerical value listed. In some embodiments, the SiN removal rate is usually less than or equal to 1000 Å/min, less than or equal to 800 Å/min, less than or equal to 600 A/, or less than or equal to 500 Å/min.

In some embodiments, the removal rate of a second material X (e.g., SoC) is greater than or equal to about 30 Å/min, greater than or equal to about 50 Å/min, greater than or equal to about 100 Å/min, greater than or equal to about 200 Å/min, greater than or equal to about 300 Å/min, greater than or equal to about 400 Å/min, greater than or equal to about 500 Å/min, greater than or equal to about 600 Å/min, or greater than or equal to 700 Å/min. In some embodiments, the removal rate of a second material X (e.g., SoC) is usually less than or equal to 2000 Å/min, or less than or equal to 1000 Å/min.

Reference will now be made in detail to some specific embodiments contemplated by the present disclosure. While various embodiments are described herein, it will be understood that it is not intended to limit the present technology to the described embodiments. On the contrary, it is intended to cover alternatives, modifications, and equivalents as may be included within the spirit and scope of the technology as defined by the appended claims.

### EXAMPLES

To test the SiN polishing rate suppressing or enhancing properties of polishing compositions according to the present disclosure, polishing compositions were prepared as discussed below and tested for enhancement or suppression of the SiN removal rate, relative to the rate of SoC removal.

### Example 1

### Example 1: Polishing Compositions Suppressing or Enhancing SiN Removal Rate

To prepare the polishing compositions shown in Tables 1 and 2 below, the following ingredients were added to 300 g deionized water, in the following amounts.
(1) SiN suppressor or enhancer;
(2) pH adjuster;
(3) 0.05 g wetting controller (N,N-dimethyldodecylamineoxide);
(4) 0.05 g biocide (MIT); and
(5) 6.5 g colloidal zirconia particles (average primary particle size=20 nm; average secondary particle size=78 nm), anionic colloidal silica A (average primary particle size=30 nm; average secondary particle size=70 nm), or anionic colloidal silica B (average primary particle size=10 nm; average secondary particle size=30 nm).

Components (1)-(4) were added to the deionized water, followed by the abrasive particles (5).

The average primary particle size of abrasive grains can be calculated based on, e.g., the specific surface area (SA) of abrasive grains, calculated by the BET method, and the density of abrasive grains. The average secondary particle size of abrasive grains can be measured by, e.g., a dynamic light scattering method typified by a laser diffraction scattering method.

### <Average Primary Particle Size of Abrasive Grains>

The average primary particle size of abrasive grains was calculated from the specific surface area of abrasive grain particles by the BET method, measured with “Flow Sorb II 2300” manufactured by Micromeritics Instrument Corporation, and the density of abrasive grains.

### <Average Secondary Particle Size of Abrasive Grains>

The average secondary particle size of abrasive grains was measured as a volume average particle size (arithmetic average size on volume basis; Mv) with a dynamic light scattering type particle size/particle size distribution apparatus UPA-UTI151 (manufactured by Nikkiso Co., Ltd.).

The anionic colloidal silica is colloidal silica on which sulfonic acid is immobilized. This can be performed by a method described in, e.g., “Sulfonic acid-functionalized silica through quantitative oxidation of thiol groups”, Chem. Commun. 246-247 (2003). Specifically, colloidal silica where sulfonic acid is immobilized on a surface of the silica can be obtained by coupling a silane coupling agent having a thiol group, such as 3-mercaptopropyltrimethoxysilane, with colloidal silica, and oxidizing the thiol group with hydrogen peroxide.

The resulting liquids were then diluted up to a total mass of 1 kg using deionized water. The polishing compositions comprising SiN suppressors/SiN enhancers are shown in Tables 1 and 2, respectively. The results of the pH measured of each of the resulting polishing compositions are shown in Tables 1 and 2.

To test the SiN and SoC removal rates, 30 mm×30 mm coupons of SoC on SiN (3000 Å SoC/1000 Å SiN/thermal SiO₂/Si wafer) or 30 mm×30 mm coupons of SiN (2500 Å SiN deposited by PECVD on Si wafer with thermal oxide) were contacted with the an IC1010 polishing pad using a table top polisher while the polishing composition was supplied to the polishing surface of the substrate, according to the following conditions: 3000 Å SoC/1000 Å SiN/thermal SiO₂/Si wafer means that SiO₂ derived from TEOS (tetraethyl orthosilicate), 1000 Å SiN, and 3000 Å SoC are stacked on a Si wafer in the listed order.

### [Conditions]

Polisher: Table top polisher
Pad: hard polyurethane pad (IC1010 manufactured by NITTA DuPont Incorporated)
Conditioner: diamond pad conditioner (A165 manufactured by 3M Company)
   Down force: 1.5 psi
Polishing table rotation: 200 rpm
   Head rotation: 230 rpm
   Slurry flow rate: 50 mL/min
Polishing time: 60 sec.

SiN and SoC removal rates were determined by comparing the SiN and SoC film thicknesses before and after polishing, using a FILMETRIX® F50-UV automated film thickness mapping system. The removal rates for various SiN suppressor compositions and SiN enhancer compositions are shown in Tables 1 and 2, respectively. The unit of the removal rate is Å/min. The SiN:X removal rate ratio (“selectivity SiN/SoC” in Tables) obtained by dividing the removal rate of SiN by the removal rate of SoC is shown in Tables 1 and 2.

TABLE 1
SiN suppressor composition

| | | Abrasive | Abrasive | | | | | | | |
|---|---|---|---|---|---|---|---|---|---|---|
| | | Size | Presence or | | | | | | | |
| | | Average | absence of | | | | | | | |
| | | primary | modification | | | | | | | |
| | | particle | of abrasive | | | SiN Suppressor/Other components | | Removal rate | | Selectivity |
| Slurry | Abrasive | size | surface | pH Adjuster | pH | Type | Conc. [g/KG] | SoC | SiN | SiN/SoC |
| 1 | Colloidal zirconia | 20 nm | — | Nitric acid | 2.4 | Arginine (L) | 0.5 | 741 | 38 | 0.051 |
| | | | | | | (Basic) | | | | |
| 2 | Colloidal zirconia | 20 nm | — | Nitric acid | 2.4 | Histidine | 0.5 | 734 | 34 | 0.046 |
| | | | | | | (Basic) | | | | |
| 3 | Colloidal zirconia | 20 nm | — | Nitric acid | 2.4 | Lysine | 0.5 | 739 | 29 | 0.039 |
| | | | | | | (Basic) | | | | |
| 4 | Colloidal zirconia | 20 nm | — | Nitric acid | 2.4 | Aspartic acid (L) | 0.5 | 754 | 2 | 0.003 |
| | | | | | | (Acidic) | | | | (0.0027) |
| 5 | Colloidal zirconia | 20 nm | — | Nitric acid | 2.4 | Glutamic acid (L) | 0.5 | 737 | 3 | 0.004 |
| | | | | | | (Acidic) | | | | (0.0041) |
| 6 | Colloidal zirconia | 20 nm | — | Nitric acid | 2.4 | Tyrosine | 0.5 | 744 | 8 | 0.011 |
| | | | | | | (containing | | | | |
| | | | | | | aromatic | | | | |
| | | | | | | hydrocarbon) | | | | |
| 7 | Colloidal zirconia | 20 nm | — | Nitric acid | 2.4 | Cysteine | 0.5 | 741 | 5.6 | 0.008 |
| | | | | | | (containing | | | | (0.0076) |
| | | | | | | sulfur atom) | | | | |
| 8 | Colloidal zirconia | 20 nm | — | Nitric acid | 2.4 | Serine | 0.5 | 701 | 28 | 0.040 |
| 9 | Colloidal zirconia | 20 nm | — | Nitric acid | 2.4 | Asparagine | 0.5 | 711 | 31 | 0.044 |
| 10 | Colloidal zirconia | 20 nm | — | Nitric acid | 2.4 | Glutamine | 0.5 | 732 | 29 | 0.040 |
| 11 | Colloidal zirconia | 20 nm | — | Nitric acid | 2.4 | — | — | 746 | 36 | 0.048 |
| 12 | Colloidal zirconia | 20 nm | — | Nitric acid | 2.4 | Glutamic acid (L) | 0.001 | 746 | 36 | 0.048 |
| | | | | | | (Acidic) | | | | |
| 13 | Colloidal zirconia | 20 nm | — | Nitric acid | 2.4 | Glutamic acid (L) | 0.01 | 746 | 9 | 0.012 |
| | | | | | | (Acidic) | | | | |
| 14 | Colloidal zirconia | 20 nm | — | Nitric acid | 2.4 | Glutamic acid (L) | 0.1 | 745 | 6 | 0.008 |
| | | | | | | (Acidic) | | | | (0.0081) |
| 15 | Colloidal zirconia | 20 nm | — | Nitric acid | 2.4 | Glutamic acid (L) | 2 | 740 | 2 | 0.003 |
| | | | | | | (Acidic) | | | | (0.0027) |
| 16 | Colloidal zirconia | 20 nm | — | Nitric acid | 2.4 | Glutamic acid (L) | 10 | 736 | 2 | 0.003 |
| | | | | | | (Acidic) | | | | (0.0027) |
| 11-1 | Anionic colloidal silica | 30 nm | Sulfonic acid | Nitric acid | 2.4 | — | — | 155 | 342 | 2.206 |
| | A | | immobilized | | | | | | | |
| 5-1 | Anionic colloidal silica | 30 nm | Sulfonic acid | Nitric acid | 2.4 | Glutamic acid (L) | 0.5 | 154 | 334 | 2.169 |
| | A | | immobilized | | | (Acidic) | | | | |
| 5-2 | Anionic colloidal silica | 10 nm | Sulfonic acid | Nitric acid | 2.4 | Glutamic acid (L) | 0.5 | 77 | 452 | 5.870 |
| | B | | immobilized | | | (Acidic) | | | | |
| 4-1 | Colloidal zirconia | 20 nm | — | Acetic acid | 2.4 | Aspartic acid (L) | 0.5 | 621 | 28 | 0.045 |
| | | | | | | (Acidic) | | | | |
| 4-2 | Colloidal zirconia | 20 nm | — | Phosphoric acid | 2.4 | Aspartic acid (L) | 0.5 | 579 | 24 | 0.041 |
| | | | | | | (Acidic) | | | | |
| 4-3 | Colloidal zirconia | 20 nm | — | Sulfuric acid | 2.4 | Aspartic acid (L) | 0.5 | 591 | 24 | 0.041 |
| | | | | | | (Acidic) | | | | |
| 4-4 | Colloidal zirconia | 20 nm | — | Etidronic acid | 2.4 | Aspartic acid (L) | 0.5 | 421 | 22 | 0.052 |
| | | | | | | (Acidic) | | | | |

TABLE 2
SiN enhancer composition

| | | | | | | SiN Enhancer | | | | | | |
|---|---|---|---|---|---|---|---|---|---|---|---|---|
| | | Abrasive | Abrasive | | | | | | Presence | | | |
| | | Size | Presence or | | | | | | or | | | |
| | | Average | absence of | | | | | | Absence | | | |
| | | primary | modification | | | | | Number of | of | | | |
| | | particle | of abrasive | pH | | | Conc. | carboxylic | hydroxyl | Removal rate | | Selectivity |
| Slurry | Abrasive | size | surface | Adjuster | pH | Type | [g/KG] | acid | groups | SoC | SiN | SiN/SoC |
| 17 | Colloidal zirconia | 20 nm | — | Nitric acid | 2.4 | Acetic acid | 0.5 | 1 | Absence | 744 | 22 | 0.030 |
| 18 | Colloidal zirconia | 20 nm | — | Nitric acid | 2.4 | Lactic acid | 0.5 | 1 | Presence | 740 | 111 | 0.150 |
| 18-1 | Colloidal zirconia | 20 nm | — | Nitric acid | 2.4 | Lactic acid | 0.05 | 1 | Presence | 746 | 88 | 0.118 |
| 19 | Colloidal zirconia | 20 nm | — | Nitric acid | 2.4 | Oxalic acid | 0.5 | 2 | Absence | 745 | 32 | 0.043 |
| 19-1 | Colloidal zirconia | 20 nm | — | Nitric acid | 2.4 | Oxalic acid | 0.05 | 2 | Absence | 744 | 34 | 0.046 |
| 20 | Colloidal zirconia | 20 nm | — | Nitric acid | 2.4 | Malonic acid | 0.5 | 2 | Absence | 740 | 43 | 0.058 |
| 21 | Colloidal zirconia | 20 nm | — | Nitric acid | 2.4 | Tartaric acid | 0.5 | 2 | Presence | 743 | 189 | 0.254 |
| 22 | Colloidal zirconia | 20 nm | — | Nitric acid | 2.4 | Malic acid | 0.5 | 2 | Presence | 732 | 222 | 0.303 |
| 23 | Colloidal zirconia | 20 nm | — | Nitric acid | 2.4 | Citric acid | 0.5 | 3 | Presence | 743 | 256 | 0.345 |
| 24 | Colloidal zirconia | 20 nm | — | Nitric acid | 2.4 | Aconitic acid | 0.5 | 3 | Absence | 743 | 28 | 0.038 |
| 25 | Colloidal zirconia | 20 nm | — | Nitric acid | 2.4 | Polyacrylic acid | 0.5 | Poly | Absence | 42 | 12 | 0.286 |
| | | | | | | (MW 5000) | | | | | | |
| 26 | Colloidal zirconia | 20 nm | — | Nitric acid | 2.4 | Polyacrylic acid | 0.5 | Poly | Absence | 33 | 11 | 0.333 |
| | | | | | | (MW100000) | | | | | | |
| 27 | Colloidal zirconia | 20 nm | — | Nitric acid | 2.4 | — | — | — | — | 746 | 36 | 0.048 |
| 28 | Colloidal zirconia | 20 nm | — | Nitric acid | 2.4 | Citric acid | 0.001 | 3 | Presence | 746 | 38 | 0.051 |
| 29 | Colloidal zirconia | 20 nm | — | Nitric acid | 2.4 | Citric acid | 0.01 | 3 | Presence | 747 | 98 | 0.131 |
| 30 | Colloidal zirconia | 20 nm | — | Nitric acid | 2.4 | Citric acid | 0.1 | 3 | Presence | 744 | 167 | 0.224 |
| 31 | Colloidal zirconia | 20 nm | — | Nitric acid | 2.4 | Citric acid | 2 | 3 | Presence | 740 | 288 | 0.389 |
| 32 | Colloidal zirconia | 20 nm | — | Nitric acid | 2.4 | Citric acid | 10 | 3 | Presence | 731 | 292 | 0.399 |

As shown in Table 1, the pH adjuster to be combined with the SiN suppressor is particularly preferably nitric acid. If any other acid is used as the pH adjuster, the action of the SiN suppressor accessing a SiN surface is presumed to be inhibited. The reason why the SoC polishing rate is slightly enhanced is considered because aggregation of abrasive grains occurs due to addition ofany other acid.

### Example 2

### Example 2: Effect of pH on SiN Polishing Rate Suppression and Enhancement

To determine the effect of composition pH on the SiN removal rate suppression or SiN removal rate enhancement, polishing compositions were prepared in the same manner as Composition 5 and Composition 23, except for varying the composition pH by varying the concentration of nitric acid. The compositions and their SiN and SoC removal rates are shown in Tables 3 and 4 below.

TABLE 3
Effect of pH on SiN polishing rate suppression

| | | | | SiN Suppressor | | Removal rate | | Selectivity |
|---|---|---|---|---|---|---|---|---|
| Slurry | Abrasive | pH Adjuster | pH | Type | Conc. [g/KG] | SoC | SiN | SiN/SoC |
| 5 | Colloidal zirconia | Nitric acid | 2.4 | Glutamic acid | 0.5 | 737 | 3 | 0.004 |
| | | | | (L) | | | | (0.0041) |
| | | | | (Acidic) | | | | |
| 33 | Colloidal zirconia | Nitric acid | 1.1 | Glutamic acid | 0.5 | 755 | 2.2 | 0.003 |
| | | | | (L) | | | | (0.0029) |
| | | | | (Acidic) | | | | |
| 34 | Colloidal zirconia | Nitric acid | 3.0 | Glutamic acid | 0.5 | 730 | 3.5 | 0.005 |
| | | | | (L) | | | | (0.0048) |
| | | | | (Acidic) | | | | |
| 35 | Colloidal zirconia | Nitric acid | 4.0 | Glutamic acid | 0.5 | 724 | 5.8 | 0.008 |
| | | | | (L) | | | | (0.0080) |
| | | | | (Acidic) | | | | |
| 36 | Colloidal zirconia | Nitric acid | 5.0 | Glutamic acid | 0.5 | 733 | 22 | 0.030 |
| | | | | (L) | | | | |
| | | | | (Acidic) | | | | |
| 37 | Colloidal zirconia | Nitric acid | 6.0 | Glutamic acid | 0.5 | 745 | 18 | 0.024 |
| | | | | (L) | | | | |
| | | | | (Acidic) | | | | |
| 38 | Colloidal zirconia | Nitric acid | 7.0 | Glutamic acid | 0.5 | 765 | 16 | 0.021 |
| | | | | (L) | | | | |
| | | | | (Acidic) | | | | |

TABLE 4
Effect of pH on SiN polishing rate enhancement

| | | | | SiN Suppressor | | Removal rate | | Selectivity |
|---|---|---|---|---|---|---|---|---|
| Slurry | Abrasive | pH Adjuster | pH | Type | Conc. [g/KG] | SoC | SiN | SiN/SoC |
| 23 | Colloidal zirconia | Nitric acid | 2.4 | Citric acid | 0.5 | 743 | 256 | 0.345 |
| 39 | Colloidal zirconia | Nitric acid | 1.4 | Citric acid | 0.5 | 744 | 255 | 0.343 |
| 40 | Colloidal zirconia | Nitric acid | 3.0 | Citric acid | 0.5 | 750 | 253 | 0.337 |
| 41 | Colloidal zirconia | Nitric acid | 4.0 | Citric acid | 0.5 | 743 | 221 | 0.297 |
| 42 | Colloidal zirconia | Nitric acid | 5.0 | Citric acid | 0.5 | 698 | 84 | 0.120 |
| 43 | Colloidal zirconia | Nitric acid | 6.0 | Citric acid | 0.5 | 674 | 25 | 0.037 |
| 44 | Colloidal zirconia | Nitric acid | 7.0 | Citric acid | 0.5 | 666 | 15 | 0.023 |

These data indicate that SiN suppressing compositions show optimal control over the SiN polishing rate (relative to SoC) at pH of less than 5. For instance, Composition 33 (pH 1.1) achieves a SiN polishing rate of 2.2 Å/min and a removal rate ratio (SiN:SoC) of 0.0029. By comparison, at pH of 5 or above, the compositions show SiN polishing rates up to an order of magnitude higher (22 Å/min at pH=5) and removal rate ratios of approximately an order of magnitude higher (0.030) than at pH 1.1.

These data indicate that SiN enhancing compositions also show optimal control over the SiN polishing rate (relative to SoC) at pH of less than or equal to 5. For instance, Composition 23 (pH 2.4) achieves a SiN polishing rate of 256 Å/min and a removal rate ratio (SiN:SoC) of 0.345. By comparison, at pH of above 5, the compositions show SiN polishing rates over an order of magnitude lower (15 Å/min at pH=7) and removal rate ratios over an order of magnitude lower (0.023) than at pH 2.4.

While certain embodiments have been illustrated and described, it should be understood that changes and modifications may be made therein in accordance with ordinary skill in the art without departing from the technology in its broader aspects as defined in the following claims.

The compositions and methods illustratively described herein may suitably be practiced in the absence of any element or elements, limitation or limitations, not specifically disclosed herein. Thus, for example, the terms “comprising”, “including,” containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof. It is recognized that various modifications are possible within the scope of the disclosure claimed. Thus, it should be understood that although the present disclosure has been specifically disclosed by preferred embodiments and optional features, modification and variation of the disclosure embodied therein herein disclosed may be resorted to by those skilled in the art, and that such modifications and variations are considered to be within the scope of this disclosure.

The disclosure has been described broadly and generically herein. Each of the narrower species and subgeneric groupings falling within the generic disclosure also form part of the methods. This includes the generic description of the methods with a proviso or negative limitation removing any subject matter from the genus, regardless of whether or not the excised material is specifically recited herein. The present technology is not to be limited in terms of the particular embodiments described in this application, which are intended as single illustrations of individual aspects of the present technology. Many modifications and variations of this present technology can be made without departing from its spirit and scope, as will be apparent to those skilled in the art. Functionally equivalent methods and apparatuses within the scope of the present technology, in addition to those enumerated herein, will be apparent to those skilled in the art from the foregoing descriptions. Such modifications and variations are intended to fall within the scope of the present technology. It is to be understood that this present technology is not limited to particular methods, reagents, compounds compositions or biological systems, which can, of course, vary. It is also to be understood that the terminology used herein is for the purpose of describing particular embodiments only, and is not intended to be limiting.

One skilled in the art readily appreciates that the present disclosure is well adapted to carry out the objects and obtain the ends and advantages mentioned, as well as those inherent therein. Modifications therein and other uses will occur to those skilled in the art. These modifications are encompassed within the spirit of the disclosure and are defined by the scope of the claims, which set forth non-limiting embodiments of the disclosure.

In addition, where features or aspects of the disclosure are described in terms of Markush groups, those skilled in the art will recognize that the disclosure is also thereby described in terms of any individual member or subgroup of members of the Markush group.

All references, articles, publications, patents, patent publications, and patent applications cited herein are incorporated by reference in their entireties for all purposes. However, mention of any reference, article, publication, patent, patent publication, and patent application cited herein is not, and should not be taken as, an acknowledgment or any form of suggestion that they constitute valid prior art or form part of the common general knowledge in any country in the world.

Other embodiments are set forth in the following claims.

1. A polishing composition comprising:
an abrasive comprising cationic particles;
a SiN polishing rate suppressor; and
water,
wherein the composition has a pH of less than 5.

2. The polishing composition of claim 1, wherein the SiN polishing rate suppressor comprises at least one selected from the group consisting of: an acidic amino acid, an amino acid comprising an aromatic hydrocarbon, and an amino acid comprising a sulfur atom.

3. The polishing composition of claim 1, wherein the SiN polishing rate suppressor comprises at least one selected from the group consisting of: aspartic acid, glutamic acid, tyrosine, and cysteine.

4. The polishing composition of claim 1, wherein the cationic particles comprise zirconia particles or surface-modified silica particles comprising a terminal amine group.

5. The polishing composition of claim 1, wherein the cationic particles are colloidal zirconia particles.

6. The polishing composition of claim 1, wherein the SiN polishing rate suppressor is present at a concentration of greater than 0.0001 wt. % and 10.0 wt. % or less, relative to the total weight of the composition.

7. The polishing composition of claim 1, wherein the composition further comprises a pH adjuster comprising nitric acid.

8. The polishing composition of claim 1, wherein the composition comprises colloidal zirconia particles, at least one selected from the group consisting of: an acidic amino acid, an amino acid comprising an aromatic hydrocarbon, and an amino acid comprising a sulfur atom, and nitric acid.

9. The polishing composition of claim 1, wherein the composition further comprises N,N-dimethyldodecylamineoxide.

10. A method of polishing a substrate comprising SiN and a second material, comprising:
polishing a surface of the substrate by contacting the surface with the composition of claim 1, wherein
the polishing rate of SiN is suppressed as compared with a case of polishing with a composition in which the SiN polishing rate suppressor in the composition of claim 1 is not added.

11. The method of claim 10, wherein the second material comprises spin-on carbon (SoC).

12. The method of claim 10, wherein the polishing is made at a ratio (SiN:X removal rate ratio) of the polishing rate of SiN to the polishing rate of the second material X, of less than 0.048.

13. A polishing composition comprising:
an abrasive comprising cationic particles;
a SiN polishing rate enhancer; and
water,
wherein the composition has a pH of less than or equal to 5.

14. The polishing composition of claim 13, wherein the SiN polishing rate enhancer comprises an acid having two or more carboxylic acid groups and one or more hydroxy groups.

15. The polishing composition of claim 13, wherein the cationic particles comprise zirconia particles or surface-modified silica particles comprising a terminal amine group.

16. The polishing composition of claim 13, wherein the cationic particles are colloidal zirconia particles.

17. The polishing composition of claim 13, wherein the SiN enhancer is present at a concentration of greater than 0.001 wt. % and 10 wt. % or less, relative to the total weight of the composition.

18. The polishing composition of claim 13, wherein the composition further comprises a pH adjuster comprising nitric acid.

19. The polishing composition of claim 13, wherein the composition comprises colloidal zirconia particles, an acid having two or more carboxylic acid groups and one or more hydroxy groups, and nitric acid.

20. The polishing composition of claim 13, wherein the composition further comprises N,N-dimethyldodecylamineoxide.

21. A method of polishing a substrate comprising SiN and a second material, comprising:
polishing a surface of the substrate by contacting the surface with the composition of claim 13, wherein
the polishing rate of SiN is enhanced as compared with a case of polishing with a composition in which the SiN polishing rate enhancer in the composition of claim 13 is not added.

22. The method of claim 21, wherein the second material comprises spin-on carbon (SoC).

23. The method of claim 21, wherein the polishing is made at a ratio (SiN:X removal rate ratio) of the polishing rate of SiN to the polishing rate of the second material X, of greater than 0.048.
